(19) United States
(12) Patent Application Publication
(10) Pub. No.: US 2025/0377408 A1
(43) Pub. Date: Dec. 11, 2025

(54) GENERATING STRUCTURED TEST VECTOR SEQUENCES FOR LOGIC VERIFICATION

(71) Applicant: International Business Machines Corporation, Armonk, NY (US)

(72) Inventors: Jordan Jhaveri, Austin, TX (US); Kevin Pradez, Austin, TX (US); Pablo Sanchez, JR., Austin, TX (US); Andrew Stephen Cassidy, Austin, TX (US)

(21) Appl. No.: 18/735,256

(22) Filed: Jun. 6, 2024

(51) Int. Cl. G01R 31/3183; G06F 30/33

(52) U.S. Cl. CPC G01R 31/318307; G06F 30/33

(57) ABSTRACT

A computer implemented system for testing an electric circuit includes training an artificial intelligence (AI) model for a specific design under test (DUT) and generating at least one control vector using the AI model and providing the at least one control vector to at least one generator. The generator generates a set of structured test vector sequences. The DUT is stimulated using the set of structured test vector sequences and produces an output from the DUT. A set of output metrics characterizing the output using an output analysis module.

### BACKGROUND

The present invention generally relates to preparing logic verification for circuit designs, and more specifically, to generating structured test vector sequences for logic verification of circuit designs.

Circuit designs area highly complex and expensive to fabricate. As such, the circuit designs require logical verification processes before fabrication in order to minimize fabrication of circuits that can be identified as faulty.

Logical verification is difficult because available systems have a limited number of simulation cycles due to timeline requirements, the state space of a simulation is too vast to fully exhaust, and human functional engineers designing the test can be biased, make mistakes, or include errors of omission when defining the state space.

### SUMMARY

Embodiments of the present invention are directed to a computer-implemented method for testing a circuit design. A non-limiting example of the computer-implemented method includes training an artificial intelligence (AI) model for a specific design under test (DUT) and generating at least one control vector using the AI model and providing the at least one control vector to at least one generator. The generator generates a set of structured test vector sequences. The DUT is stimulated using the set of structured test vector sequences and produces an output from the DUT. A set of output metrics characterizing the output using an output analysis module.

Further embodiments of the present invention are directed to a computer program products, computing environments, and system for the same.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 depicts one exemplary cloud computing system configured to implement the system and method according to one embodiment;

FIG. 2 depicts an exemplary process for generating test vectors for logical verification of circuits;

FIG. 3 depicts a training flow for the exemplary process of FIG. 2;

FIG. 4 depicts a run flow for the exemplary process of FIG. 2;

FIG. 5 depicts a first example test pattern generator utilizing a numerical sequence process;

FIG. 6 depicts a second example test pattern generator utilizing an instruction sequence process;

FIG. 7 depicts a third example test pattern generator utilizing contiguous instruction sequences;

FIG. 8 depicts a fourth example test pattern generator utilizing finite state model sequences;

FIG. 9 depicts a fifth example test pattern generator using probabilistic model generated sequences; and

FIG. 10 depicts a sixth example test generator using machine learning generative model sequences.

The diagrams depicted herein are illustrative. There can be many variations to the diagram or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the disclosed embodiments, the various elements illustrated in the figures are provided with two or three digit reference numbers. With minor exceptions, the leftmost digit(s) of each reference number correspond to the figure in which its element is first illustrated.

### DETAILED DESCRIPTION

Various embodiments of the invention are described herein with reference to the related drawings. Alternative embodiments of the invention can be devised without departing from the scope of this invention. Various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. Moreover, the various tasks and process steps described herein can be incorporated into a more comprehensive procedure or process having additional steps or functionality not described in detail herein.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” may be understood to include any integer number greater than or equal to one, i.e. one, two, three, four, etc. The terms “a plurality” may be understood to include any integer number greater than or equal to two, i.e. two, three, four, five, etc. The term “connection” may include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of +8% or 5%, or 2% of a given value.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

Computing environment 100 contains an example of an environment for the execution of at least some of the computer code involved in performing the inventive methods, such as generating structured test vector sequences for logic verification at block 150. In addition to block 150, computing environment 100 includes, for example, computer 101, wide area network (WAN) 102, end user device (EUD) 103, remote server 104, public Cloud 105, and private Cloud 106. In this embodiment, computer 101 includes processor set 110 (including processing circuitry 120 and cache 121), communication fabric 111, volatile memory 112, persistent storage 113 (including operating system 122 and block 150, as identified above), peripheral device set 114 (including user interface (UI), device set 123, storage 124, and Internet of Things (IoT) sensor set 125), and network module 115. Remote server 104 includes remote database 132. Public Cloud 105 includes gateway 130, Cloud orchestration module 131, host physical machine set 132, virtual machine set 143, and container set 144.

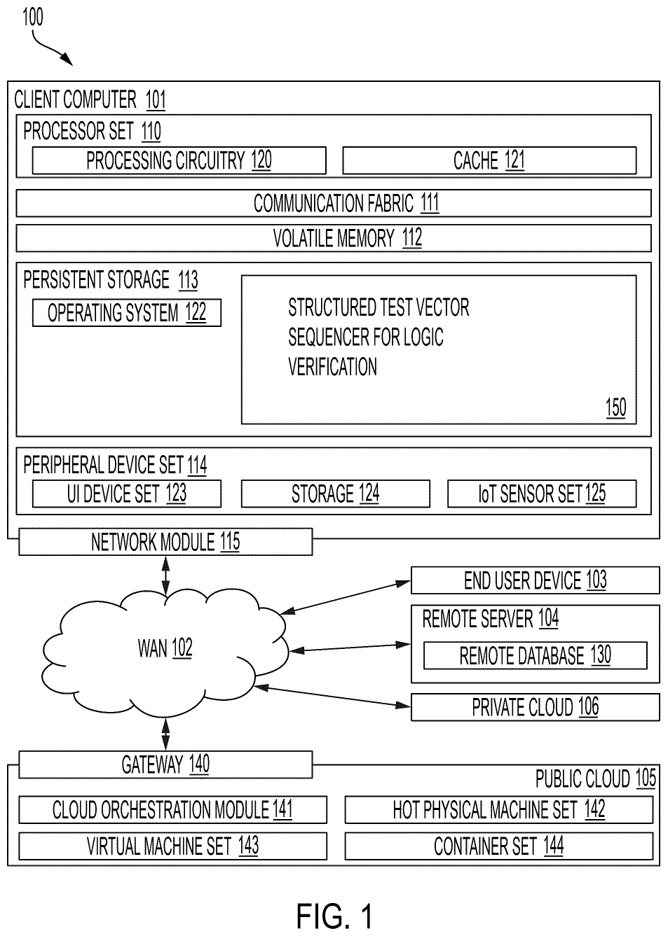

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 132. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a Cloud, even though it is not shown in a Cloud in FIG. 1. On the other hand, computer 101 is not required to be in a Cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 150 in persistent storage 113.

COMMUNICATION FABRIC 111 is the signal conduction paths that allow the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, the volatile memory is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface type operating systems that employ a kernel. The code included in block 150 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collects and store helpful and useful data for use by other computers, such as computer 101. For example, in a hypothetical case where computer 101 is designed and programmed to provide a recommendation based on historical data, then this historical data may be provided to computer 101 from remote database 132 of remote server 104.

PUBLIC CLOUD 105 is any computer system available for use by multiple entities that provides on-demand availability of computer system resources and/or other computer capabilities, especially data storage (Cloud storage) and computing power, without direct active management by the user. Cloud computing typically leverages sharing of resources to achieve coherence and economies of scale. The direct and active management of the computing resources of public Cloud 105 is performed by the computer hardware and/or software of Cloud orchestration module 131. The computing resources provided by public Cloud 105 are typically implemented by virtual computing environments that run on various computers making up the computers of host physical machine set 132, which is the universe of physical computers in and/or available to public Cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 131 manages the transfer and storage of images, deploys new instantiations of VCEs and manages active instantiations of VCE deployments. Gateway 130 is the collection of computer software, hardware, and firmware that allows public Cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public Cloud 105, except that the computing resources are only available for use by a single enterprise. While private Cloud 106 is depicted as being in communication with WAN 102, in other embodiments a private Cloud may be disconnected from the internet entirely and only accessible through a local/private network. A hybrid Cloud is a composition of multiple Clouds of different types (for example, private, community or public Cloud types), often respectively implemented by different vendors. Each of the multiple Clouds remains a separate and discrete entity, but the larger hybrid Cloud architecture is bound together by standardized or proprietary technology that enables orchestration, management, and/or data/application portability between the multiple constituent Clouds. In this embodiment, public Cloud 105 and private Cloud 106 are both part of a larger hybrid Cloud.

One or more embodiments described herein can utilize machine learning (alternately referred throughout as AI) techniques to perform prediction and or classification tasks, for example. In one or more embodiments, machine learning functionality can be implemented using an artificial neural network (ANN) having the capability to be trained to perform a function. In machine learning and cognitive science, ANNs are a family of statistical learning models inspired by the biological neural networks of animals, and in particular the brain. ANNs can be used to estimate or approximate systems and functions that depend on a large number of inputs. Convolutional neural networks (CNN) are a class of deep, feed-forward ANNs that are particularly useful at tasks such as, but not limited to analyzing visual imagery and natural language processing (NLP). Recurrent neural networks (RNN) are another class of deep, feed-forward ANNs and are particularly useful at tasks such as, but not limited to, unsegmented connected handwriting recognition and speech recognition. Other types of neural networks are also known and can be used in accordance with one or more embodiments described herein.

ANNs can be embodied systems of interconnected elements that act as simulated “neurons”. The connections in ANNs between simulated neurons are provided with numeric weights that correspond to the strength or weakness of a given connection. The weights can be adjusted and tuned based on experience, making ANNs adaptive to inputs and capable of learning. For example, an ANN for handwriting recognition is defined by a set of input neurons that can be activated by the pixels of an input image. After being weighted and transformed by a function determined by the network's designer, the activation of these input neurons are then passed to other downstream neurons, which are often referred to as “hidden” neurons. This process is repeated until an output neuron is activated. The activated output neuron determines which character was input.

A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Turning now to an overview of technologies that are more specifically relevant to aspects of the invention, fabrication expenses for complex circuits can be on the order of tens of millions of dollars and is time consuming. Major bugs discovered after fabrication can take at least six months to fix. As such, a goal of circuit design is to find the majority of problems and implement solutions during the verification process before actual chip fabrication. However, verification is difficult due to a limited number of simulation cycles on a limited timeline. As a result of the limited timeline, the objective is to find and fix all bugs before time ends. Exacerbating this difficulty is the fact that the state space of a simulation is too vast to fully explore all possibilities within the timeline. As a result, typically only a sample is tested with the sample being selected by a functional verification engineer.

Functional verification engineers can be biased, make mistakes, or make errors of omission during state space exploration. The process could be improved by minimizing the role of the functional verification engineer in designing the sample space for the functional test. Use of targeted test vectors can allow for the state space coverage to be increased while decreasing the probability of errors propagating through fabrication.

Turning now to an overview of the aspects of the invention, one or more embodiments of the invention address the above-described shortcomings of the prior art by providing an AI model to predict Design Under Test (DUT) performance for a circuit verification process. The predicted performance is used order to generate targeted control vectors. Targeted Test Vectors contain ordered data or structured fields and are neither random nor constrained random. The system addresses specific performance metrics such as: latency, throughput, transaction rates, backpressure, utilization, coverage, power consumption, and command rate, etc.

The trained AI model generates control vectors given a target metric specification. Given the control vectors, the generators create targeted test vectors. The test vectors are executed on the DUT. An output analysis unit measures the performance of the DUT. The system exercises the DUT at a specified level of performance. This approach is a hands-off approach, meaning the mechanisms contained in the system iteratively generates control vectors, test vectors/patterns, and executes the tests to fruition.

Training a model to predict design output metrics for given input stimuli, and using the trained model to generate input stimuli to achieve a specified metric improves the cost-efficiency of the verification and bug finding process for a circuit.

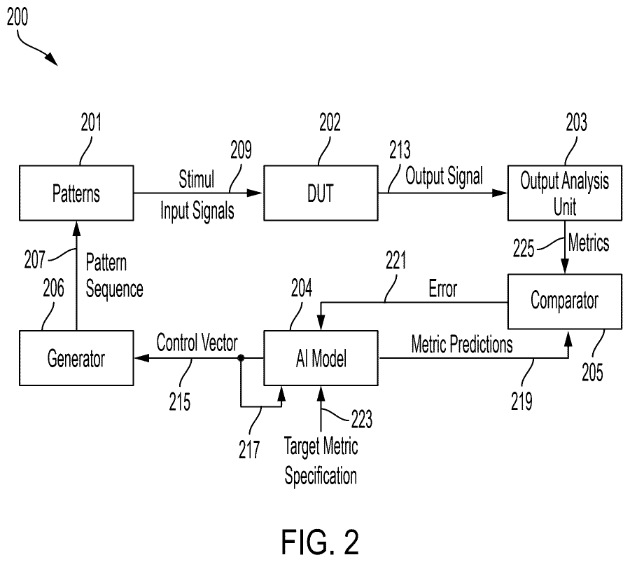

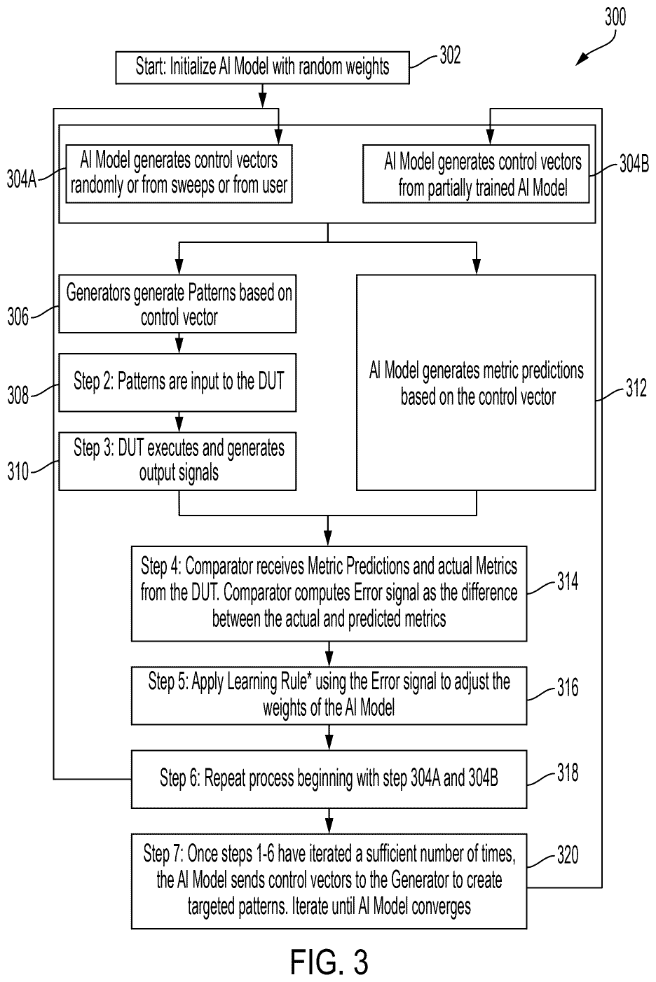

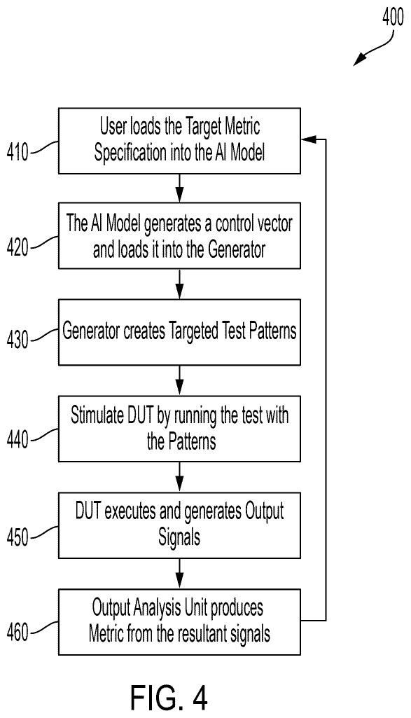

Turning now to a more detailed description of aspects of the present invention, FIG. 2 depicts a system 200 for developing test vectors for logical verification of circuits according to embodiments of the invention. FIG. 3 depicts a training flow 300 for using the system 200 of FIG. 2 to train a machine learning model to provide vectors to a generator for creating targeted patterns. FIG. 4 illustrates a run flow 400 for using the system 200 of FIG. 2 to generate a performance metric for designing an analysis state space for a given circuit.

With reference to FIG. 2, the components within the system 200 of FIG. 2 include a pattern module 201, a design under test module 202, an output analysis unit 203, an AI model 204, a comparator 205, and a generator 206.

The pattern module 201 contains pattern sequences 207, alternately referred to as test vectors. The pattern sequences 207 from the pattern module 201 are injected into the design under test (DUT) 202 to allow the DUT 202 to exercise its functionality. The pattern sequences 207 can include possible states, transitions, computations, and logical operations. In other examples, the pattern sequences 207 can include additional patterns, and implementations are not limited to the specifically enumerated patterns. The objective of the pattern sequences 207 is to stimulate the entire functionality of, and place stress on, the logical component of the DUT 202 in order to expose errors in the functional correctness of the particular design. Pattern sequences drive signals dynamically during a test of the DUT 202 and set variables that are static during a test of the DUT 202. One type of a variable is a dial. A dial is a hardware defined entity that allows verification engineers to adjust aspects of the high-level design functionality. Examples of dials can include frequencies, command rate, voltage regulations, sensor reactivity, balancing links, and turning off and on features of the DUT 202.

The design under test 202 is a logical description of the electronic circuit component design that is to be evaluated using the system 200, and the processes 300 (FIG. 3) and 400 (FIG. 4.) The design component of the DUT 202 is, in some examples, written in a hardware description language (HDL) and the objective of the system 200 is to verify the functional correctness of the electronic circuit component's design (the DUT 202).

The output analysis module 203 receives output signals from the DUT 202 and calculates output metrics by counting transitions and assertions on the output signals. The output analysis module 203 combines signal metrics into a usable aggregate performance metric 225. The performance metric 225 is a measure of the functionality exercised. Good performance exercises the functionality of the DUT 202 in its entirety. During a training flow (process 300 of FIG. 3) the output analysis module 203 provides metrics 225 to the comparator 205 for training the AI Model 204. During a test flow (process 400 of FIG. 4) the functional test engineer specifies the target performance of the system. The output analysis module 203 provides metrics 225 of the actual performance of the system, that should reasonably match the specified target performance metric.

The comparator 205 receives the metrics from the output analysis module 203 as well as metric predictions 219 from the AI model 204 and compares the latter against the former, thus comparing the inferences to the real data. The comparison results in an error signal 221 that provides feedback on the correctness of the metric predictions from the AI Model 204 during the training flow process 300 of FIG. 3.

The AI Model 204 receives stimuli from Pattern sequences 201 in a first example, the control vector 215 in a second example, or both in a third example. Using the stimuli, the AI model 204 makes predictions of the performance metric that would be measured from exercising the DUT 202. The AI model 204 outputs a control vector 215 to the generator 206 to produce pattern sequences 207 that form a targeted test vector patterns for the patterns 201. The control vectors 215 are based on a desired metric 225. The AI Model 204 is trained in the training flow process 400 of FIG. 4 by comparing generated metric predictions 219 to the metrics 225 provided by the output analysis module 203 using the comparator 205 to compute the difference between the metric predictions 219 and the metrics 225. One example of AI Model that can be used in the system 200 to make this kind of metric prediction from input patterns and adjust from difference/error value(s) is a logistical regression model. The logical regression model can apply learning rules are in conjunction with the error 221 value(s) to the AI Model 204 such that the AI model 204 can adjust the weights of nodes as it receives feedback on its inferencing. By way of example, the weights can be adjusted for back propagation of error in a neural network based AI model, and/or for least squares for a regression based model.

The generator 206 produces pattern sequences 207 that form the pattern 201 based on a control vector 215 from the AI Model 204. The pattern 201 exercises the desired functionality in the DUT 202. Generator types can include random data generation, lists of viable instructions or commands, lists of contiguous instruction sequences, finite state machine of commands including random start locations and random interrupts or stops, probabilistic sequence models such as HMMs and Bayesian networks, and generative neural networks. Generative AI Models, such as generative neural networks, autoencoders, and transformers generate data given a prompt or seed according to a learned representation of data sequences. The goal of the generator 206 is to produce targeted test vectors that cover the state space. In the example of using a logistical regression AI Model as the AI model 204, the AI Model 204 outputs a control vector 215 which comprises parameters from the regression model, such as ranges, means, or standard deviations. In one example, the generator 206 generates random samples from a uniform data distribution given a range parameter in the control vector 215 within which to operate. In another example, the generator 206 generates random samples from a normal distribution given a standard deviation and mean parameters in the control vector 215 within which to operate. Examples of stimuli 209 that can be provided from the generator as part of the pattern sequences 207 include opcodes, latch-drive finite state machines, primary/secondary finite state machines, cache traffic, bus traffic packet/network traffic, addresses, data, control, modes, arbitration, sequences of states, sequences of commands, data flows, and point of coherency using low power connectors and high power connectors. In some examples, the stimuli 209 can be provided one or more different DUT 202 input ports including buses, control signals, memory, clocks, features and parameters, models, selects, configs, dials, voltages, sync signals, and handshake signals.

With reference now to FIGS. 2, 3, and 4 for a given design (DUT 202) to be analyzed, the training flow 300 is run to generate a corresponding AI model 204 then the run flow 400 is run to develop the test space. As each circuit being tested is distinct, a generalized AI model or test space is not implemented using the system 200.

Referring to FIGS. 2 and 3, the training flow 300 begins by initializing a starting AI model 204 in a start step 302. The initial values may be random weights or predetermined values. The AI model 302 generates control vectors 205 randomly or using sweeps from a user in step 304A and begins two parallel process branches (steps 306, 308 and 310 in a first branch and step 312 in a second branch).

In the first branch, the AI model 302 outputs the control vectors to a generator 206 and the generators 206 generate pattern sequences 207 based on the control vectors 215 (Step 306). The pattern sequences 207 are saved as patterns 201 and provided to a design under testing (DUT) module 202 (Step 308). The DUT module 202 operates the circuit design using stimuli 209 from the patterns 201 and generates output signals 203 which are provided to an output analysis module 203 (step 310).

In the second branch, the AI model 204 iteratively generates metric predictions 217 based on the control vectors from steps 304A and 304B in step 312.

During the training flow 300, steps 306, 308, 310 and step 312 are executed simultaneously.

After completion of steps 310 and 312, metrics 225 are provided from the output analysis module 203 to a comparator 205 in step 314. The comparator 205 also receives metric predictions 219 from the AI model 204. The comparator 205 generates an error signal 221, and the error signal 221 is provided back to the AI model 204 in step 314. The error signal 221 is the difference between the generated metrics 225 and the metric predictions 219.

The AI model 204 applies learning rules (e.g. regression models such as least squares, or neural network AI models such as back propagation of error) using the error signal 221 to adjust the weights of the AI model 204 in step 316.

After adjusting the weights, step 318 determines if the process 300 has been sufficiently iterated to fully train the AI model 204. When the process 300 has not been sufficiently iterated, step 318 causes the process 300 to be reiterated beginning at steps 304A, 304B.

When step 318 determines that the process 300 has been sufficiently iterated, the process 300 proceeds to a step 320. At step 320, the AI model 204 sends control vectors 215 to the generator 206 to create targeted patterns, and the step 320 is iterated until the AI model 204 converges, after which the process 300 has fully trained the system 200 and the run flow process 400 of FIG. 4 can begin.

With reference now to FIG. 2 and FIG. 4, after the system 200 has been fully trained, the process 300 of the training flow ceases, and a process 400 for generating performance metrics 225 is employed. In the process 400, initially a functional test engineer uploads target metric specifications 223 into the AI model 204 in a step 410.

Once the target metric specifications 223 have been received, the AI model 204 generates a control vector 215 and loads the control vector 215 into the generator 206 at step 420. The generator 206 then creates pattern sequences 207 that are consolidated into patterns 201 at step 430. At step 440, the DUT 202 is stimulated using the stimuli of the patterns 201.

After the DUT 202 has been stimulated, the DUT 202 executes and generates output signals 213 in a step 450, and the output signals 213 are provided to the output analysis unit 203. The output analysis unit 203 then produces and outputs performance metrics 225 based on the resultant signals from the DUT 202. A functional test engineer specifies the performance metrics targets for the system. The system generates test vectors that stimulate the DUT 202 within the target performance range. Then bug testing on the DUT 202 can be performed, while the DUT 202 is exercised at the specified performance metric.

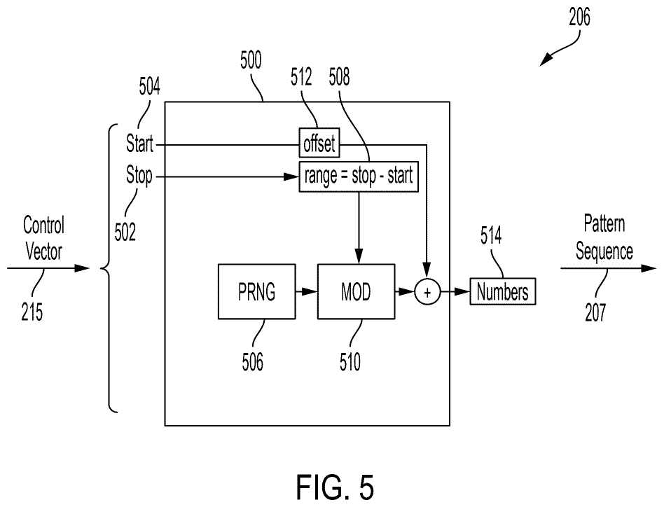

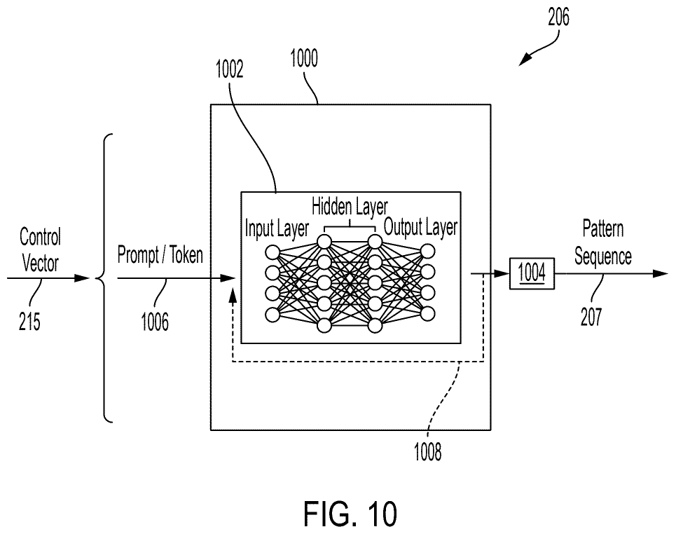

FIGS. 5-10 illustrate example generator 206 configurations. In each configuration, the generator 206 receives the control vector 215 containing all necessary inputs, and outputs pattern sequences 207.

With continued reference to FIGS. 1-4, FIG. 5 illustrates a first example generator 206 configured to generate numerical sequences (numerical sequence generator 500). In the illustrated numerical sequence embodiment, the control vector 215 comprises two parameters: stop 502 and start 504. In other numerical sequence embodiments, the control vector 215 could include ranges, offsets, function control (shifts, XORs), or any similar parameters. A pseudo random number generator (PRNG 506) generates a sequence of random integers. A range 508 is computed as the stop 502 parameter minus the start 504 parameter. The range is applied as a modulo 510 to the output of the PRNG 506. The offset 512 is the start 504 parameter. The offset 512 is applied to the output of the modulo 510 function. The result is a sequence of numbers 514 within the specified range. The generator 206 of FIG. 5 is an example of a simple random number sequence generator that is controlled by the AI Model 204.

With continued reference to FIGS. 1-5, FIG. 6 illustrates a second example generator 206 configured to generate instruction sequences. The instruction sequence generator 600 incorporates the numerical sequence generator 500 of FIG. 5 as a sub-component. A list of viable instructions or commands are stored in a data structure 606 including one instruction or command at each address of the data structure 606. Data structure embodiments include arrays, lists, linked-lists, vectors, and matrices. The AI Model 204 produces a control vector 215 of control parameters, including the start 504, stop 502 parameters as well as a stride 602 and shift 604 parameter. The start 504 and stop 502 parameters are applied to the numerical sequence generator 500 to produce the numeric sequence 514. The stride 602 and shift 604 parameters are applied to the numeric sequence 514 to generate a sequence of addresses into a data structure 606. The data structure 606 returns a sequence of instructions and commands 608 which is output as the pattern sequence 207. The instruction sequence generator 600 is an example of a generator 206 that is biased by the AI Model 204 to generate non-numeric random sequences of instructions or commands.

With continued reference to FIGS. 1-6, FIG. 7 illustrates a third example generator 206 configured to generate contiguous instruction sequences. The contiguous instruction sequence generator 700 incorporates the numerical sequence generator 500 of FIG. 5 as a sub-component and incorporates an additional list of sequences 702 into the structure of the basic instruction sequence generator 600.

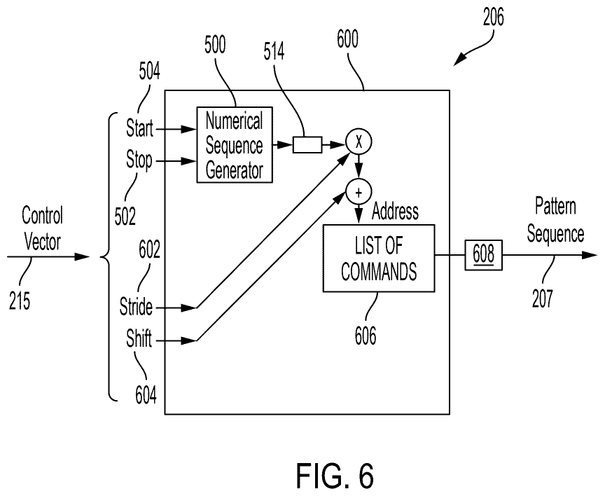

A list of sequences are stored in a sequence data structure 702. In one example, each sequence is stored at a unique address in the sequence data structure and is defined by a starting address 706, a stopping address 708, a repetition count 710, and a duration 712. A sequence address is generated in the same manner as the address of in the address for the instruction and command database 606 in the instruction sequence generator 600 of FIG. 6. The sequence address is provided to the sequence data structure 702 and indexes into the corresponding sequence list 704. From the sequence list 704 entry, a series of instruction addresses are generated from a start address 706 to a stop address 708. Additional parameters may be included in the sequence list entry, such as repetition count 710 and/or a sequence duration 712. The series of instruction addresses are then provided to the instruction and command data structure 606 and the instructions and command data structure 606 returns a sequence of consecutive instructions or commands for each sequence list entry. The contiguous instruction sequence generator 700 is used to generate a contiguous set of instructions, such as structured packet fields or microcode functions.

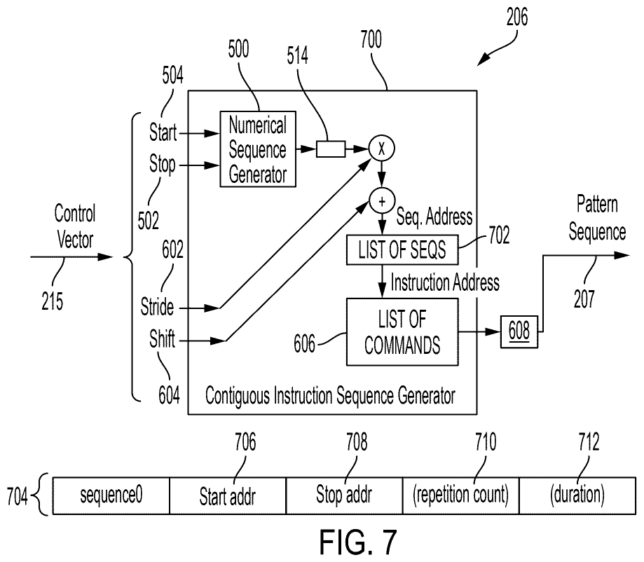

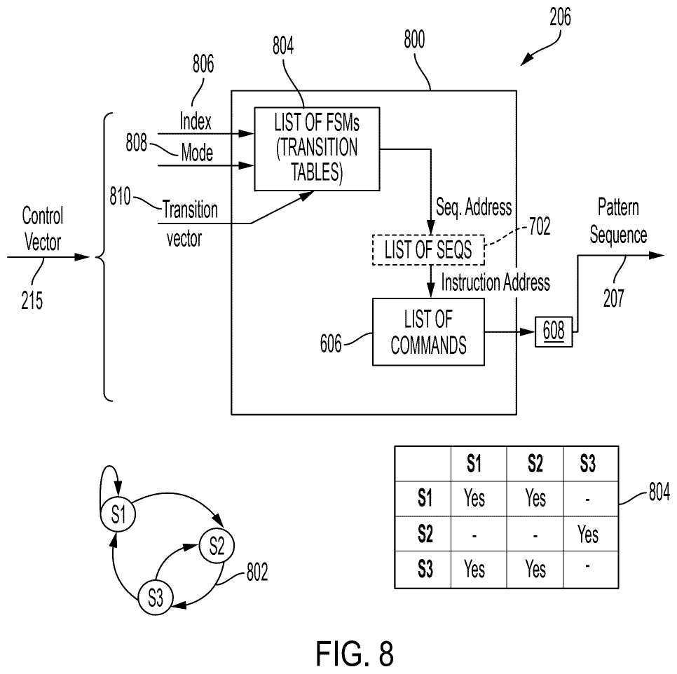

With continued reference to FIGS. 1-4, FIG. 8 illustrates an example generator 206 configured as a finite state machine sequence generator 800. In the finite state machine sequence generator 800, an address is generated using a finite state machine (FSM 802) instead of the numerical sequence generator 500. The FSM 802 is diagrammatically represented in FIG. 8 as a transition table 804. The FSM 802 simulates sequential logic and is composed of a finite number of states S1, S2, S3, and only one state S1, S2, S3 can be occupied at a time. The inputs to the FSM 802 determine the next state S1, S2, S3 and the outputs of the FSM 802. The finite state machine sequence generator 800 is, as a result, a deterministic model. In the example of FIG. 8, the control vector 215 includes an index 806, a mode, 808, and a transition vector 810. In one embodiment, the transition table 804 itself may be configured by the AI Model 204 as a part of the control vector 215. The address generated by the FSM 804 is provided either directly to the data structure 606, or optionally to the sequence data structure 702, which provides an output to the data structure 606 in the same manner as the examples of FIGS. 7 and 8. The finite state machine generator 800 generates structured sets of instructions, without storing an entire trace in the list of commands. While illustrated in FIG. 8 as an FSM 802 include three states and five transitions, it is appreciated that practical examples may include substantially more states, and a correspondingly increased number of transitions.

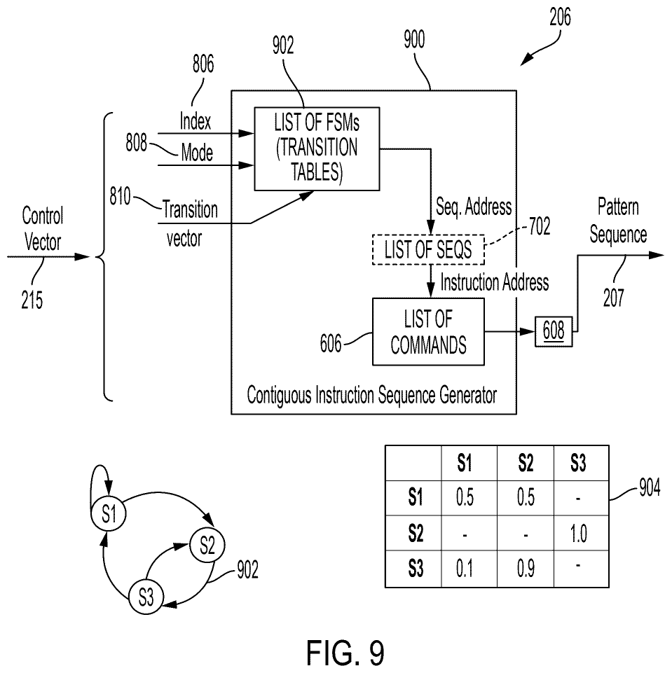

With continued reference to FIGS. 1-4, and FIG. 8, FIG. 9 illustrates a probabilistic model sequence generator 900 that can be used as the generator 206 of FIG. 2. Instead of using the FSM 802 to generate the addresses (as in the finite state machine sequence generator 800), the addresses in the probabilistic model sequence generator 900 are generated using probabilistic models 902, such as Markov Chains, Bayesian Networks, or other probabilistic graphical models. The probabilistic model 902 operates similar to the FSM 802 of FIG. 8, except the binary transitions in the FSM 802 transition table 804 are replaced with transition probabilities in transition table 904. Given a current state, the state machine 902 transitions to any outgoing state with the probability given in the transition table 904. Similarly, in one example, the transition table itself may be configured by the AI Model 204 as a part of the control vector 215. The probabilistic model sequence generator 900 is used to generate stochastic sets of instructions according to probabilistic distributions. While illustrated in FIG. 9 as a probabilistic model 902 include three states and five transitions, it is appreciated that practical examples may include substantially more states, and a correspondingly increased number of transitions.

With continued reference to FIGS. 1-4, FIG. 10 illustrates an example AI model sequence generator 1000 that can be used as the generator 206 of FIG. 2. The AI model sequence generator 1000 can be used to generate sequences of instructions in the form of traces. In the AI model sequence generator 1000, a generative neural network 1002 is utilized to generate instruction sequences 1004 that are output as the pattern sequence 207. As used herein, an instruction trace is the sequence of instructions during execution of the DUT 202. These sequences of instructions are analogous to sequences of words in human language, and it is appreciated that Large Language Models (LLMs) are generative neural networks for human language. Instruction traces from existing designs are used to train a generative model of viable sequences. The AI model sequence generator 1000 is tuned to suit the user's need using a subset of viable traces. Once tuned, the AI model 204 provides a prompt or token 1006 as the control vector 215 to generate an instruction 1004. The prompt or token 1006 is fed into the generative neural network 1002, which produces the next token in the sequence given the model and the prior tokens of the sequence. The generated token is fed back into the input of the generative neural network via a feedback loop 1008 to generate the next, and this process is reiterated, generating a complete instruction trace 1004.

To train the generative neural network model 1002, pattern sequences 207 from a training dataset are used. For each pattern sequence 207 in the training data set that is used, an instruction is randomly dropped from the pattern sequence 207. The dropped instruction is retained in a memory and is the correct answer that the generative neural network 1002 is trying to predict. The generative neural network model weights are adjusted using a backpropagation of error technique based on a correct/incorrect prediction of the dropped instruction during a training iteration. This process is repeated multiple times for every pattern sequence in the training dataset by randomly dropping different instructions each pass. The process is repeated until the generative neural network 1002 model converges (prediction error is minimized). In some examples, a reduced training data set size can be used by reusing pattern sequences and dropping an instruction from the pattern sequence than any previous iterations using that particular pattern sequence 207. Further, accuracy of the generative neural network 1002 can be verified after training by re-running the process on early pattern sequences, dropping the same instruction that was previously dropped.

Referring to FIGS. 2 and 5-10, while illustrated as distinct sequence generators 206, it is appreciated that the generator 206 may include multiple of the example generator types (illustrated in FIGS. 5-10) operating in conjunction to generate the generate the patterns 207

Referring collectively to the embodiments illustrated in FIGS. 1-10, the AI model 204 learns a model of the DUT 202 and is a predictor of the objective function. This enables direct feedback control from a measured metric to the control vector 215 provided to the generator 206 using only the AI model 204. In one embodiment, the learned representation of the AI model 204 utilizes regression methods (linear and non-linear). Regression models are fast to train, start with few examples, and can be continually updated as additional simulations are run using the least squares algorithm (and pseudoinverse). In addition, regression models are fast to evaluate and have smoothing properties by construction. The smoothing properties average out noise and potential local minima.

In some examples, the system 200 can include additional steps or stages in the feedback control loop from the measured metric 225 to the generators 206 (including the comparator 205, the AI model 204, the error value 221, and the metric predictions). In some examples, the additions can include derivative free optimization techniques or use the AI model 204 as a classifier on the patterns 207 output by the generator 206, instead of as a regressor controlling the generator 206.

Among other uses of the circuit verification system 200, the systems and process described herein can be beneficially utilized in the verification of designs that include workload optimization features, where the hardware is subject to changing frequency and voltage proportional to the components' utilization. One such example is a system where a component's utilization of resources degrades the performance of neighboring components, whether that be in available power or transaction rate, among other things. Workload performance must be set to target these conditions.

The systems and processes described herein can further be beneficially utilized in the verification of designs that include workload optimization features where the hardware features mitigate temperature spikes and leakage current in caches and execution units by changing frequency and voltage while optimizing for the workload. There is an increasing effort to verify these features in pre-silicon development as opposed to post-fabrication validation, and workload performance must be set to target these conditions.

The systems and processes described herein can further be beneficially utilized in the verification of interconnect fabric performance where scalability is the largest obstacle to overcome. The more cores and threads (i.e., more computational power) being utilized the more load there is on the data communication and memory hierarchy units outside the CPU. When the load gets too large, the network can saturate, resulting in higher latency for cache misses, leading to higher cache miss penalty, then higher CPI. Therefore, metrics such as command latency and utilization must be optimized to ultimately lower the CPI (cycles per instruction) of a system.

The systems and processes described herein can further be beneficially utilized in the verification of hardware dedicated to interrupt handling and servicing, where servicing and arbitrations latencies and communication protocols are concerned and where transaction rate is a very important metric that designs must account for (i.e an engine must be able to service a request within 500 us because the polling speed for requests is such and such. If transitions are not serviced before next request is received, does it get lost, etc.).

The systems and processes described herein can further be beneficially utilized in the verification of memory protocols, such as cache coherency where exploring ranges or regions of transaction rates is required to reveal issues within the protocol.

The systems and processes described herein can further be beneficially utilized in the verification of memory interfaces where rejected fetches or fetches resulting in memory access negatively impacts data latency. Early knowledge of this allows for improvements on arbitration logic and better support of high-intensity workloads.

The systems and processes described herein can further be beneficially utilized in the verification of backpressure in hardware designs where the configuration of multiple transaction generators is important to put the design into performance regimes that will appropriately exercise the backpressure at multiple locations in the design.

The systems and processes described herein can further be beneficially utilized in the verification of hardware accelerators where the performance of the design is an important metric for consideration in verification. If the throughput of a hardware accelerator is not optimized or does not perform faster or with a lesser cost than software constructs during verification, it is very costly to fix during validation.

The systems and processes described herein can further be beneficially utilized in the verification of physical design where power consumption must be characterized across performance levels. Power consumption is estimated after synthesizing hardware description language (HDL) and executing gate-level simulation, which is significantly slower than logic-level simulation, so generating appropriate test configurations is even more important.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instruction by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A computer implemented method comprising:
training an artificial intelligence (AI) model for a specific design under test (DUT);
generating at least one control vector using the AI model and providing the at least one control vector to at least one generator;
generating a set of structured test vector sequences using the at least one generator;
stimulating the DUT using the set of structured test vector sequences and producing an output from the DUT; and
generating a set of output metrics characterizing the output using an output analysis module.

2. The computer implemented method of claim 1, wherein training the AI model comprises:
initializing the AI model and beginning a training process, the training process including:
generating training control vectors using the AI model and generating output metric predictions using the AI model based on the training control vectors;
providing the training control vectors to the at least one generator and generating a training set of structured test vector sequences using the at least one generator, stimulating the DUT using the training set of structured test vector sequences and producing an output from the DUT, and generating a set of training output metrics characterizing the output using the output analysis module;
comparing the set of training output metrics to the output metric predictions using a comparator, thereby determining an error signal representative of a correctness of the output metric predictions; and
adjusting at least one parameters of the AI model based on the error signal; and
reiterating the training process until the error signal converges with the output metric predictions.

3. The computer-implemented method of claim 1, wherein the at least one generator includes a numerical sequence generator.

4. The computer-implemented method of claim 1, wherein the at least one generator includes an instruction sequence generator.

5. The computer-implemented method of claim 1, wherein the at least one generator includes a continuous instruction sequence generator.

6. The computer-implemented method of claim 1, wherein the at least one generator includes a finite state machine based sequence generator.

7. The computer-implemented method of claim 1, wherein the at least one generator includes a probabilistic model based sequence generator.

8. The computer-implemented method of claim 1, wherein the at least one generator includes an artificial intelligence based sequence generator.

9. The computer-implemented method of claim 1, wherein the DUT is a circuit design.

10. The computer-implemented method of claim 9, wherein each test vector sequence in the set of structured test vector sequences includes a plurality of variables, each variable being configured to stimulate at least one input port of the DUT.

11. The computer-implemented method of claim 10, wherein the at least one input port of the DUT contains at least one of: statically configured input ports and dynamically stimulated input ports.

12. The computer-implemented method of claim 10, wherein the statically configured input ports of the DUT include at least one of a frequency, a command rate, a voltage regulation, a sensor reactivity, a balancing link, and an on/off feature toggle.

13. A computing environment comprising:
a communication fabric connecting a set of processing circuitry, a volatile memory, and a nonvolatile memory;
the nonvolatile memory storing instructions for causing the computing environment to perform the steps of:
training an artificial intelligence (AI) model for a specific design under test (DUT);
generating at least one control vector using the AI model and providing the at least one control vector to at least one generator;
generating a set of structured test vector sequences using the at least one generator;
stimulating the DUT using the set of structured test vector sequences and producing an output from the DUT; and
generating a set of output metrics characterizing the output using an output analysis module.

14. The computing environment of claim 13, wherein training the AI model comprises:
initializing the AI model and beginning a training process, the training process including:
generating training control vectors using the AI model and generating output metric predictions using the AI model based on the training control vectors;
providing the training control vectors to the at least one generator and generating a training set of structured test vector sequences using the at least one generator, stimulating the DUT using the training set of structured test vector sequences and producing an output from the DUT, and generating a set of training output metrics characterizing the output using the output analysis module;
comparing the set of training output metrics to the output metric predictions using a comparator, thereby determining an error signal representative of a correctness of the output metric predictions; and
adjusting the weights of the AI model based on the error signal; and
reiterating the training process until the error signal converges with the output metric predictions.

15. The computing environment of claim 13, wherein the at least one generator includes at least one of a numerical sequence generator, an instruction sequence generator, a continuous instruction sequence generator, a finite state machine based sequence generator, a probabilistic model based sequence generator, and an artificial intelligence based sequence generator.

16. The computing environment of claim 13, wherein the DUT is a circuit design.

17. The computing environment of claim 16, wherein each test vector sequence in the set of structured test vector sequences includes a plurality of variables, each variable being configured to stimulate at least one input port of the DUT.

18. The computing environment of claim 17, wherein the statically configured input ports of the DUT include at least one of a frequency, a command rate, a voltage regulation, a sensor reactivity, a balancing link, and an on/off feature toggle.

19. A computer program product comprising:
a nonvolatile memory storing instructions for causing a computing environment to perform the steps of:
training an artificial intelligence (AI) model for a specific design under test (DUT);
generating at least one control vector using the AI model and providing the at least one control vector to at least one generator;
generating a set of structured test vector sequences using the at least one generator;
stimulating the DUT using the set of structured test vector sequences and producing an output from the DUT; and
generating a set of output metrics characterizing the output using an output analysis module.

20. The computer program product of claim 12, wherein training the AI model comprises:
initializing the AI model using weights having randomly assigned values and beginning a training process, the training process including:
generating training control vectors using the AI model and generating output metric predictions using the AI model based on the training control vectors;
providing the training control vectors to the at least one generator and generating a training set of structured test vector sequences using the at least one generator, stimulating the DUT using the training set of structured test vector sequences and producing an output from the DUT, and generating a set of training output metrics characterizing the output using the output analysis module;
comparing the set of training output metrics to the output metric predictions using a comparator, thereby determining an error signal representative of a correctness of the output metric predictions; and
adjusting the weights of the AI model based on the error signal; and
reiterating the training process until the error signal converges with the output metric predictions.
